(19) United States
(12) Patent Application Publication
(10) Pub. No.: US 2025/0254943 A1
(43) Pub. Date: Aug. 7, 2025

(54) Power Semiconductor Devices with Stacked Layers

(71) Applicant: Wolfspeed, Inc., Durham, NC (US)

(72) Inventors: Thomas Edgar Harrington, III, Durham, NC (US); Callie Marie Woods, Durham, NC (US)

(21) Appl. No.: 18/430,866

(22) Filed: Feb. 2, 2024

(51) Int. Cl. H01L 29/06; H01L 21/04; H01L 21/265; H01L 27/092; H01L 29/16; H01L 29/20; H01L 29/739; H01L 29/78

(52) U.S. Cl. CPC H10D 62/124; H01L 21/046; H01L 21/26546; H10D 12/441; H10D 30/66; H10D 62/111; H10D 62/8325; H10D 62/8503; H10D 84/85

(57) ABSTRACT

Semiconductor device are provided. In one example, a semiconductor device includes a substrate. The semiconductor device includes a plurality of semiconductor layers on the substrate. The plurality of semiconductor layers are bonded to one another in a stacked arrangement.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Schottky Barrier Diodes (“SBD”), Gate Turn-Off Transistors (“GTO”), junction field effect transistors (“JFET”), high electron mobility transistors (“HEMT”) and other devices. Example semiconductor devices may be diodes, such as Schottky diodes or other devices. Example semiconductor devices may be power modules, which may include one or more power devices and other circuit components and can be used, for instance, to dynamically switch large amounts of power through various components, such as motors, inverters, generators, and the like. These semiconductor devices may be fabricated from wide bandgap semiconductor materials, such as silicon carbide (“SiC”) and/or gallium nitride (“GaN”) based semiconductor materials.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a substrate. The semiconductor device includes a plurality of semiconductor layers on the substrate. The plurality of semiconductor layers are bonded to one another in a stacked arrangement.

Another example aspect of the present disclosure is directed to a method for fabricating a semiconductor device. The method includes bonding first surface of a wide bandgap epitaxial layer on a first surface of a carrier substrate. The method includes separating a portion of the wide bandgap epitaxial layer to provide a first semiconductor layer remaining on the carrier substrate. The method includes bonding a second semiconductor layer on a second surface of the first semiconductor layer to form a stacked arrangement.

Another example aspect of the present disclosure is directed to a semiconductor device. The semiconductor device includes a substrate. The semiconductor device includes a semiconductor structure comprising a plurality of semiconductor layers on the substrate. The plurality of semiconductor layers are bonded to one another in a stacked arrangement wherein at least one of the plurality of semiconductor layers comprises a doped column. The doped column having a thickness of about 2 microns or greater. The semiconductor device includes a gate contact on the doped column.

Another example aspect of the present disclosure is directed to a superjunction MOSFET device. The MOSFET device may include a substrate. The MOSFET device may include a semiconductor structure comprising a plurality of semiconductor layers on the substrate. The plurality of semiconductor layers are bonded to one another in a stacked arrangement. The plurality of semiconductor layers comprise a first semiconductor layer having a first doped region and a second semiconductor layer having a second doped region. The first doped region and the second doped region are aligned to form a doped column in the semiconductor structure.

Another example aspect of the present disclosure is directed a bipolar CMOS-DMOS (BCDMOS) device. The BCDMOS device may include a substrate. The BCDMOS device may include a wide bandgap semiconductor structure comprising a plurality of semiconductor layers on the substrate. The plurality of semiconductor layers are bonded to one another in a stacked arrangement. The BCDMOS device may include a deep well region extending across two or more of the plurality of semiconductor layers. The deep well region comprises a bipolar device region and a CMOS device region.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts an overview of an example method according to example embodiments of the present disclosure;

FIG. 2 depicts a cross-sectional view of a semiconductor device according to example embodiments of the present disclosure;

FIG. 3 depicts an overview of an example method according to example embodiments of the present disclosure;

FIG. 4 depicts a cross-sectional view of a semiconductor device according to example embodiments of the present disclosure;

FIG. 5 depicts a cross-sectional view of a semiconductor device according to example embodiments of the present disclosure;

FIG. 6 depicts an overview of an example method according to example embodiments of the present disclosure;

FIG. 7 depicts an overview of an example method according to example embodiments of the present disclosure;

FIG. 8 depicts a cross-sectional view of an example semiconductor device according to example embodiments of the present disclosure;

FIG. 9 depicts a cross-sectional view of an example semiconductor device according to example embodiments of the present disclosure;

FIG. 10 depicts a cross-sectional view of an example semiconductor device according to example embodiments of the present disclosure; and

FIG. 11 depicts a cross-sectional view of an example semiconductor device according to example embodiments of the present disclosure.

FIG. 12 depicts a cross-sectional view of an example semiconductor device according to example embodiments of the present disclosure.

FIG. 13 depicts a cross-sectional view of an example semiconductor device according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials, without deviating from the scope of the present disclosure. Example wide bandgap semiconductor materials include silicon carbide (e.g., 2.996 eV band gap for alpha silicon carbide at room temperature) and the Group III-nitrides (e.g., 3.36 eV band gap for gallium nitride at room temperature).

Aspects of the present disclosure are discussed with reference to wide bandgap semiconductor structures for purposes of illustration and discussion. Those of ordinary skill in the art, using the disclosures provided herein, will understand that aspects of the present disclosure are applicable with other semiconductor structures, such as silicon-based semiconductor structures, without deviating from the scope of the present disclosure.

Power semiconductor devices can have a lateral structure or a vertical structure. In a device having a lateral structure, the terminals of the device (e.g., the drain, gate and source terminals for a power MOSFET device) are on the same major surface (e.g., top surface or bottom surface) of a semiconductor structure. In contrast, in a power semiconductor device having a vertical structure, at least one terminal is provided on each major surface of the semiconductor structure. For instance, in a vertical MOSFET device, the source may be on the top surface of the semiconductor structure and the drain may be on the bottom surface of the semiconductor structure, or vice versa.

Power semiconductor devices are often fabricated by performing fabrication processes on semiconductor wafers. The semiconductor wafers may include one or more epitaxial layers formed on a substrate. As used herein an “epitaxial layer” is a single-crystal semiconductor layer grown on top of a substrate using a process called epitaxial growth or epitaxy. The epitaxial layer may be deposited atom by atom and may adopt the crystal structure of the underlying substrate. An epitaxial layer may have a thickness in a range of, for instance, about 0.05 microns to about 200 microns.

A “substrate” refers to a solid semiconductor material upon which epitaxial layers may be formed. A substrate may be a homogenous material, such as silicon carbide and/or sapphire and may provide mechanical support for the formation and/or carrying of epitaxial layers. In many examples, substrates may be provided as a semiconductor wafer on which various other layers and structures are formed or otherwise provided. A substrate may have a thickness in a range of about 5 microns to about 1000 microns, or greater. A “growth substrate” refers to a substrate on which an epitaxial layer is formed. A “carrier substrate” refers to a substrate on which an epitaxial layer may not be initially formed, but otherwise has an epitaxial layer or other semiconductor layer provided on the substrate.

Power semiconductor devices may require the formation of doped regions in localized areas of a silicon carbide-based epitaxial layer. The doped regions may be formed, for instance, by dopant implantation (e.g., ion implantation). However, due to the limitations of dopant diffusion in silicon carbide, it may be difficult to establish certain doping profiles or structures in a silicon carbide-based power semiconductor device. For instance, it may be difficult to establish doping profiles that extend deep (e.g., about 0.2 microns or greater) into a silicon carbide-based semiconductor structure. This may be particularly true due to the limitations of high energy available in ion implantation tools and the ability of masking layers to block high energy.

One approach that does allow for establishment of arbitrary and deep doping structures in localized regions of an epitaxial layer is a multi-epitaxial layer growth approach. In a multi-epitaxial layer growth approach, a first epitaxial layer is formed. A mask is patterned on the first epitaxial layer and a first dopant implantation process is performed to implant dopants into the first epitaxial layer. A second epitaxial layer is then formed (e.g., grown) on the first epitaxial layer. The process is then repeated for multiple layers until a desired depth/dopant profile is achieved.

Aspects of the present disclosure are directed to semiconductor structures having multiple thin semiconductor layers that are bonded to one another in a stacked arrangement. Each of the thin layers is a separated portion of a larger epitaxial layer. The thin layers may be each the same semiconductor material (e.g., silicon carbide) or may be different semiconductor layers. For instance, a first semiconductor layer may be a first semiconductor material (e.g., silicon carbide) and a second semiconductor layer may be a second semiconductor material (e.g., silicon, Group III-nitride, sapphire, etc.). Each of the thin semiconductor layers can be implanted to provide a doping profile. The thin semiconductor layers may be stacked on a front side and/or a backside of a substrate to form a desired doping profile (e.g., with deep dopant structures) in the semiconductor structure for a semiconductor device, such as a JFET, MOSFET, IGBT, or complex device, such as a bipolar-CMOS-DMOS device.

For instance, according to example aspects of the present disclosure, a separation process (e.g., using implantation or one or more lasers to form a separation plane) may be used to separate thin epitaxial layers from a larger wide bandgap epitaxial layer to create multiple thin layers. Each of the thin epitaxial semiconductor layers may be implanted with dopants to provide doped regions in the thin epitaxial layers. The thin layers are bonded and stacked to provide a stacked arrangement.

In one example, a wide bandgap epitaxial layer is formed on a growth substrate (e.g., by epitaxial growth/deposition). A desired doping profile is provided in the wide bandgap epitaxial layer by either using dopant implantation of one or more doping species into the topside of the wide bandgap epitaxial layer before the thin layer is separated, and/or by doping the epitaxial layer on the topside epitaxial deposition. A separation plane (e.g., cleavage plane) may be provided in the wide bandgap epitaxial layer. The separation plane may be formed, for instance, using implantation (e.g., hydrogen implantation) and/or by inducing laser damage regions in the wide bandgap epitaxial layer with one or more lasers. The wide bandgap epitaxial layer and growth substrate are flipped and provided on a carrier wafer. A portion of the wide bandgap epitaxial layer is separated from the growth substrate and the remainder of the wide bandgap epitaxial layer along the separation plane such that a thin semiconductor layer is remaining on the carrier substrate. This process may be repeated such that semiconductor layers are stacked and bonded one-by-one onto the carrier substrate.

In some examples, after bonding the to the carrier substrate, and subsequent split-off of the thin layer from the donor wafer, the thin layer can optionally be implanted again to further build up a cumulative doping structure. In this manner, aspects of the present disclosure provide a method of creating device doping structures in silicon carbide or other wide bandgap semiconductor structures using multiple stacked and doped thin layers that are difficult to create by methods like, for instance, dopant diffusion and ion implantation.

Aspects of the present disclosure provide technical effects and benefits. For instance, aspects of the present disclosure allow for control of doping structures from both sides of a thin layer, and not just from one side as in the multi-epitaxial layer growth approaches. Control and/or design of the doping structure from both sides will result in more precise doping profiles, allowing for unique top and bottom of layer doping profiles. This also allows for thicker individual epitaxial layers compared to the multi-epitaxial layer growth approaches. Thicker individual layers means that aspects of the present disclosure may require fewer layers for building up the final structure, resulting in time and cost and complexity savings. This may be beneficial when trying to create doping structures in silicon carbide because dopant diffusion in silicon carbide using high temperatures poses significant challenges.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

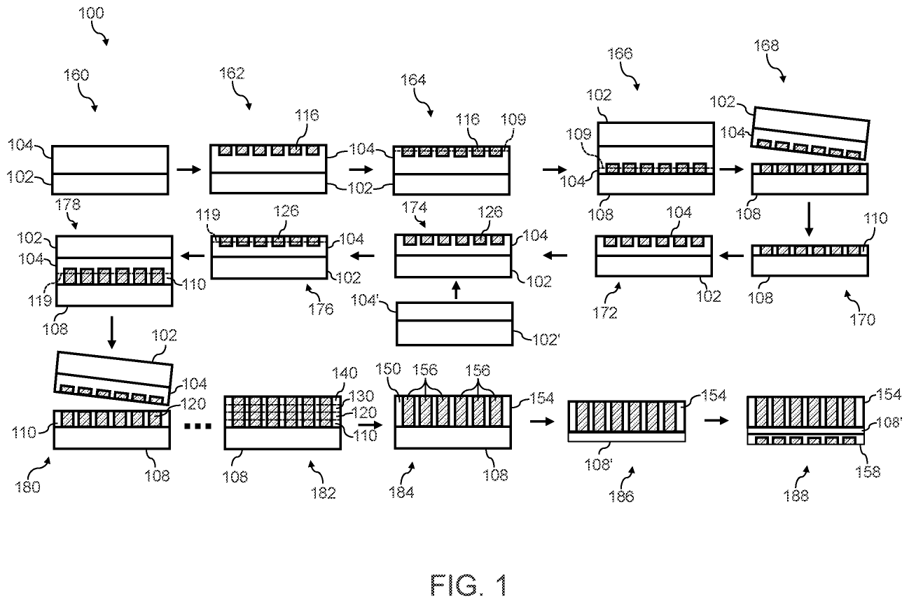

FIG. 1 depicts an overview of an example method 100 according to example embodiments of the present disclosure. FIG. 1 is intended to represent structures for identification and description and is not intended to represent the structures to physical scale. The method 100 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 160, the method 100 may include forming a wide bandgap epitaxial layer 104 on a growth substrate 102. The growth substrate 102 may be a semiconductor material. For instance, the growth substrate 102 may be a silicon substrate, a silicon carbide substrate, a sapphire substrate, or other suitable substrate. In some embodiments, the growth substrate 102 may be a semi-insulating silicon carbide substrate that may be, for example, the 4H polytype of silicon carbide. Other suitable substrates may be used as the growth substrate 102 without deviating from the scope of the present disclosure.

The wide bandgap epitaxial layer 104 may be formed by epitaxial growth on the growth substrate 102. The wide bandgap epitaxial layer 104 may be, in some embodiments, a silicon carbide epitaxial layer. The wide bandgap epitaxial layer 104 may be, in some embodiments, a Group III-nitride. As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. The wide bandgap epitaxial layer 104 may be formed using any suitable epitaxial growth process, such as hybrid vapor phase epitaxy (HVPE), metal-organic vapor phase epitaxy (MOVPE), molecular beam epitaxy (MBE), or other suitable growth process.

At 162, the method 100 may include implanting dopants into the wide bandgap epitaxial layer 104 to form one or more first doped regions 116. For instance, an implant process may create the one or more first doped regions 116 in the wide bandgap epitaxial layer 104. The dopants may be implanted using a dopant implantation process (e.g., ion implantation process). The implant process may be a low energy or a high energy implant process. In some examples, the implant process may be a multi-implant process with differing implant energies and/or doses. In some examples, the dopants may be implanted with masking to form a pattern such that the first doped regions 116 are patterned doped regions. Alternatively, the first doped regions 116 may be formed during the epitaxial growth process of the wide bandgap epitaxial layer 104 (e.g., in instances where the first doped regions 116 are more uniform across the wide bandgap epitaxial layer 104 and not patterned).

In some embodiments, the dopants implanted into the wide bandgap epitaxial layer may be selected such that the first doped regions 116 have a first conductivity type (e.g., such that the first doped regions are n-type). In some embodiments, the dopants implanted into the wide bandgap epitaxial layer may be selected such that the first doped regions 116 have a second conductivity type (e.g. such that the second doped regions are p-type). The implant conditions associated with the implant process may be selected to provide a desired or specified dopant concentration in the first doped regions 116. For instance, the dose and energy of implanted dopants may be selected during the implant process to provide a desired dopant concentration in the first doped regions 116.

At 164, the method 100 may include providing a separation plane 109 in the wide bandgap epitaxial layer 104. In some embodiments, providing the separation plane 109 may include implanting one or more species (e.g., hydrogen) into the wide bandgap epitaxial layer 104. The species may induce damage in the wide bandgap epitaxial layer 104 to form the separation plane. In some embodiments, forming the separation plane may include emitting one or more lasers into the wide bandgap epitaxial layer 104 to form a laser damaged region in the wide bandgap epitaxial layer along the separation plane 109. In some embodiments, the separation plane 109 extends through the first doped regions 116. Aspects of the present disclosure are discussed with reference to a “separation plane” for purposes of illustration and discussion. However, the term “separation plane” is not limited to a planar shape or structure but may include complex or irregular shapes.

At 166, the method 100 may include bonding the first surface of the wide bandgap epitaxial layer 104 onto the substrate 108. In some embodiments, the substrate 108 may be a carrier substrate. In some embodiments, the substrate 108 may be a silicon carbide substrate or a polycrystalline silicon carbide substrate. Other suitable substrates may be used as the substrate 108 without deviating from the scope of the present disclosure, such as a silicon substrate or a sapphire substrate.

The wide bandgap epitaxial layer 104 may be bonded to the substrate 108 using a bonding process. The bonding process may be a direct bonding or fusion bonding process where the wide bandgap epitaxial layer 104 is directly bonded to the carrier substrate 108 with no intervening structures or layers between the substrate 108 and the wide bandgap epitaxial layer 104. The direct bonding process may be based, for instance, on van der Waals forces, covalent bonds, or other bonding between the substrate 108 and the wide bandgap epitaxial layer 104. A plasma pretreatment process or other pretreatment process may be performed on the surface(s) of the substrate 108 and/or the wide bandgap epitaxial layer 104 to prepare for the direct bonding of the wide bandgap epitaxial layer 104 to the substrate 108.

At 168, the method may include separating a portion of the wide bandgap epitaxial layer 104 to provide a first semiconductor layer 110 remaining on the substrate 108. An assembly including the substrate 108 and first semiconductor layer 110 is illustrated at 170. In some embodiments, the wide bandgap epitaxial layer 104 may be separated along the separation plane 109.

FIG. 1 illustrates at 172 the remaining portion of the wide bandgap epitaxial layer 104 on the growth substrate 102 after the separation process. At 174, the method 100 may include implanting dopants into a remaining portion of the wide bandgap epitaxial layer 104 to form one or more second doped regions 126. In some embodiments, the one or more second doped regions 126 may be identical in conductivity type and/or concentration to the one or more first doped regions 116. In some embodiments, the one or more second doped regions 126 may have different conductivity type and/or concentration relative to the one or more first doped regions 116.

In some examples, prior to implanting dopants at 174, the method may include grinding, lapping, polishing, etching (e.g., wet or dry etch), oxide-based removal process (e.g., oxidation process and oxide removal process), or otherwise removing at least a part of the remaining portion of the wide bandgap epitaxial layer 104 to ensure that no remaining doped regions remain on the wide bandgap epitaxial layer 104. In this way, the implant conditions do not have to be altered, for instance, to provide the one or more second doped regions 126 that are identical in conductivity type and/or concentration to the one or more first doped regions 116. In some examples, the location of the separation plane 109 may be selected such that the separation plane 109 does not intersect the doped regions 116 to provide for the remaining portion of the wide bandgap epitaxial layer 104 to be free from doped regions prior to implanting dopants at 174.

In some examples, it may be desirable to leave a portion of the doped regions 116 remaining on the wide bandgap epitaxial layer 104 prior to implanting dopants at 174. In these examples, the separation plane 109 may intersect the first doped regions 116 to provide for a portion of the first doped regions 116 to be remaining on the wide bandgap epitaxial layer 104 prior to implanting dopants at 174.

In some examples, instead of using the remaining portion of the wide bandgap epitaxial layer 104 on the growth substrate 102, the method 100 may use a new epitaxial layer 104′ on a different growth substrate 102′. In some examples, the new epitaxial layer 104′ may be a different semiconductor material relative to the epitaxial layer 104. At 174, the method 100 may include implanting dopants into the new wide bandgap epitaxial layer 104′ to form one or more second doped regions 126. In some embodiments, the one or more second doped regions 126 may be identical in conductivity type and/or concentration to the one or more first doped regions 116. In some embodiments, the one or more second doped regions 126 may have different conductivity type and/or concentration relative to the one or more first doped regions 116.

At 176, the method 100 may include providing a separation plane 119 in the remaining portion of the wide bandgap epitaxial layer 104. Like the separation plane 109, the separation plane 119 may include implanting one or more species into the wide bandgap epitaxial layer 104 or emitting one or more lasers into the wide bandgap epitaxial layer 104. The separation plane 119 may extend through the one or more second doped regions 126.

At 178, the method 100 may include bonding the remaining portion of the wide bandgap epitaxial layer 104 on a surface of the first semiconductor layer 110. The wide bandgap epitaxial layer 104 may be bonded to the first semiconductor layer 110 using a bonding process. The bonding process may be a direct bonding or fusion bonding process where the wide bandgap epitaxial layer 104 is directly bonded to the first semiconductor layer 110 with no intervening structures or layers between the first semiconductor layer 110 and the wide bandgap epitaxial layer 104. The direct bonding process may be based, for instance, on van der Waals forces, covalent bonds, or other bonding between the first semiconductor layer 110 and the wide bandgap epitaxial layer 104. A plasma pretreatment process or other pretreatment process may be performed on the surface(s) of the first semiconductor layer 110 and/or the wide bandgap epitaxial layer 104 to prepare for the direct bonding of the wide bandgap epitaxial layer 104 to the first semiconductor layer 110.

At 180, the method 100 includes separating a second portion of the remaining portion of the wide bandgap epitaxial layer 104 on the first semiconductor layer 110. In other words, the remaining portion of the wide bandgap epitaxial layer 104 may be separated such that a second semiconductor layer 120 is bonded to the surface of the first semiconductor layer 110. In some embodiments, the second semiconductor layer 120 may be bonded to the first semiconductor layer 110 to form a stacked arrangement. The first semiconductor layer 110 and second semiconductor layer 120 may be stacked such that the first doped regions 116 are aligned with the second doped regions 126. In some embodiments, the first doped regions 116 may not be aligned with the second doped regions 126.

In some embodiments the first doped regions 116 and second doped regions 126 may each have a first conductivity type. For example, the first doped regions 116 and second doped regions 126 may be p-type regions. In some embodiments, the first doped regions 116 may be a first conductivity type and the second doped regions 126 may be a second conductivity type. For instance, the first doped regions 116 may be p-type regions and the second doped regions 126 may be n-type regions. In some embodiments, the first doped regions 116 and second doped regions 126 may each include a dopant concentration. The dopant concentration of the first doped regions 116 may be the same as or different than the dopant concentration of the second doped regions 126.

In some embodiments, the first semiconductor layer 110 and second semiconductor layer 120 may each have a thickness in a range of about 0.05 microns to about 200 microns, such as about 1 micron to about 100 microns, such as about 10 microns to about 50 microns. In some embodiments, the first semiconductor layer 110 and the second semiconductor layer 120 may have about the same thickness. In some embodiments, the first semiconductor layer 110 and the second semiconductor layer 120 may have different thicknesses. The first semiconductor layer 110 and second semiconductor layer 120 may also include different materials. In some embodiments, the first semiconductor layer 110 and the second semiconductor layer 120 may each include silicon carbide or a Group III-nitride.

The operations and processes discussed in 172-180 of FIG. 1 may be repeated to form a plurality of semiconductor layers on the substrate 108 as depicted at 182. For instance, the operations in 172-180 may be performed to create a first semiconductor layer 110, a second semiconductor layer 120, a third semiconductor layer 130, and a fourth semiconductor layer 140 on the substrate 108.

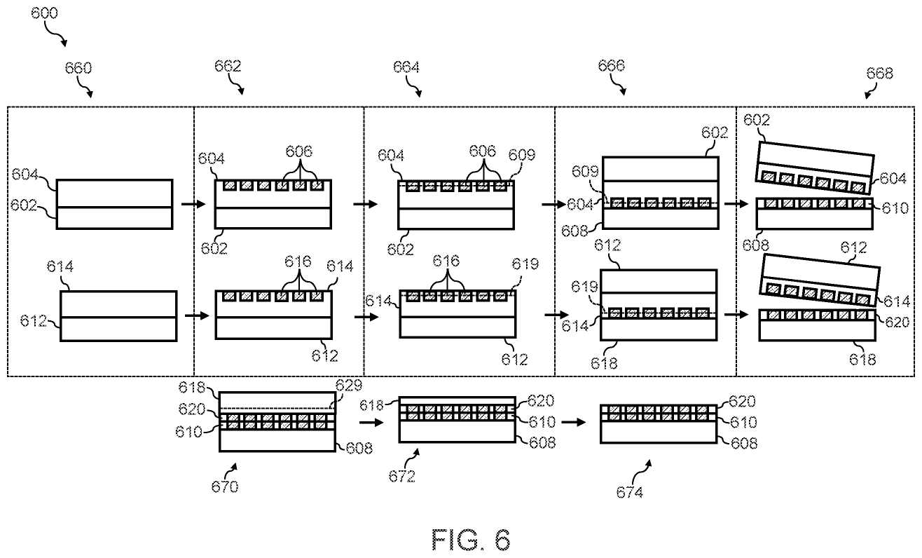

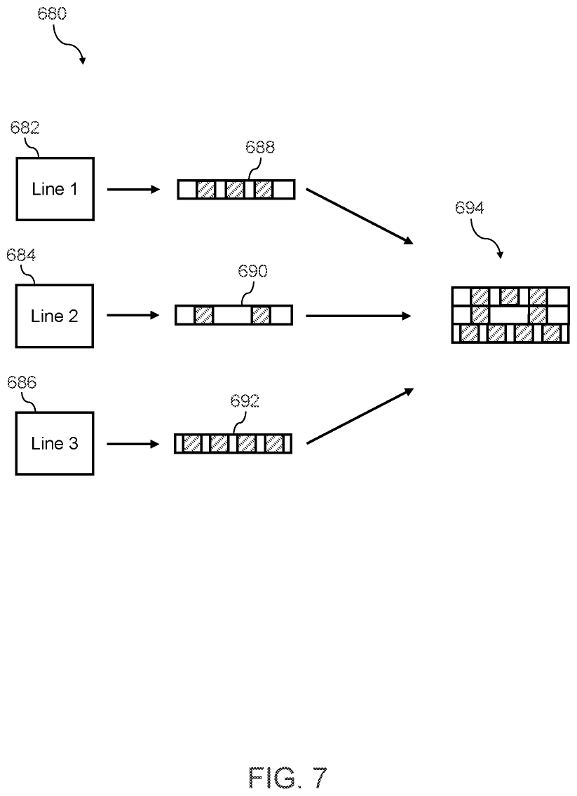

A semiconductor device 150 with four semiconductor layers 110, 120, 130, and 140 is depicted at 184 of FIG. 1. The semiconductor device 150 may include deep implant regions 156 in a semiconductor structure 154 on the substrate 108. In some embodiments, as discussed with reference to FIG. 6, additional growth substrate(s) may be used instead of the remaining portion of the wide bandgap epitaxial layer 104 to complete and repeat the operations depicted in 172-180. For example, the one or more second doped regions 126 may be implanted in a second epitaxial layer on a second growth substrate and bonded to the first semiconductor layer 110 on the substrate 108. In this way, as will be described with reference to FIGS. 6 and 7 below, the formation of layers may be performed in parallel to significantly reduce fabrication time.

FIG. 1 depicts a semiconductor device 150 with four semiconductor layers for purposes of illustration and discussion. Those of ordinary skill in the art, using the disclosures provided herein, will understand that the semiconductor device 150 may include more or fewer semiconductor layers without deviating from the scope of the present disclosure.

In some examples, the method 100 may include further processing to provide one or more semiconductor layers on a backside of the substrate 108. For instance, at 186, the method 100 may include performing a thinning operation (e.g., a grinding operation, a laser-based removal operation, etching operation, oxidation operation, or other operation) to remove material from the backside of the substrate 108 to yield a thinned substrate 108′. At 188, a semiconductor layer 158 formed according to example embodiments of the present disclosure (e.g., using implantation and separation) may be bonded to the backside of the substrate 108′. The semiconductor layer 158 may be a separated portion of one or more wide bandgap epitaxial layers. Additional semiconductor layers may be stacked on the semiconductor layer 158. In some examples, the substrate 108 is removed altogether and the semiconductor layer 158 is bonded to the semiconductor structure 154.

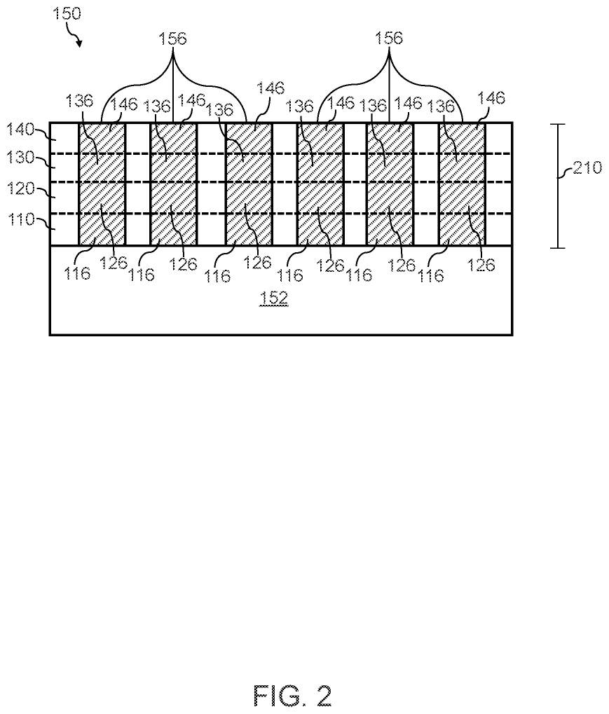

FIG. 2 depicts a cross-sectional view of an example semiconductor device 150 according to examples embodiments of the present disclosure. The semiconductor device 150 may include the substrate 152 (e.g., carrier substrate 108 of FIG. 1) and a plurality of semiconductor layers 210. Each of the plurality of semiconductor layers 210 may be a separated portion of one or more wide bandgap epitaxial layers 104 as discussed with reference to FIG. 1. In some embodiments, the plurality of semiconductor layers 210 may be bonded to one another in a stacked arrangement. The plurality of semiconductor layers 210 may include several layers, for instance a first semiconductor layer 110 and a second semiconductor layer 120 as depicted in FIG. 1. The plurality of semiconductor layers 210 may each include a doped region which is aligned and stacked to create a plurality of deep implant regions 156 (e.g., doped columns). In some embodiments, each doped region may be different, creating distinct doped regions for each of the plurality of semiconductor layers 210.

In some embodiments, the semiconductor device 150 may include a third semiconductor layer 130 with one or more third doped regions 136. The plurality of semiconductor layers 210 may be stacked and arranged such that the third doped regions 136 is aligned and stacked with the first doped regions 116 and second doped regions 126. The third doped regions 136 may be similar to the first doped regions 116 and second doped regions 126. For instance, the third doped region, as well as the first and second, may include implanted dopants.

In some embodiments, the plurality of semiconductor layers may include a fourth semiconductor layer 140 with one or more fourth doped regions 146. In some embodiments, the plurality of semiconductor layers 210 may be stacked and arranged such that the fourth doped regions 146 is aligned and stacked with the first doped regions 116, second doped regions 126, and third doped regions 136. Similar to the first doped regions 116 and second doped regions 126, the third doped regions 136 and fourth doped regions 146 may include a conductivity type and dopant concentration. The third doped regions 136 and fourth doped regions 146 may include the same or different conductivity types and/or dopant concentrations relative to each other and/or relative the first doped regions 116 and second doped regions 126.

Each of the plurality of semiconductor layers 210 may have a thickness. The thickness of each layer may be in a range of about 0.05 microns to about 200 microns, such as about 1 micron to about 100 microns, such as about 10 microns to about 50 microns. In some embodiments, each of the plurality of semiconductor layers 210 may have the same thickness relative to one another. In some embodiments, one or more of the plurality of semiconductor layers 210 may have a different thickness.

Each of the plurality of semiconductor layers 210 may be a wide bandgap semiconductor, such as silicon carbide or a Group III-nitride. The stacked layer structure of the semiconductor device 150 may be used to form a variety of semiconductor devices, such as silicon carbide-based non-charge-balanced devices and charge-balanced (superjunction) devices (e.g., SBDs, JFETs, IGBTs, MOSFETs) or complex devices, such as Bipolar-CMOS-DMOS (BCD) devices.

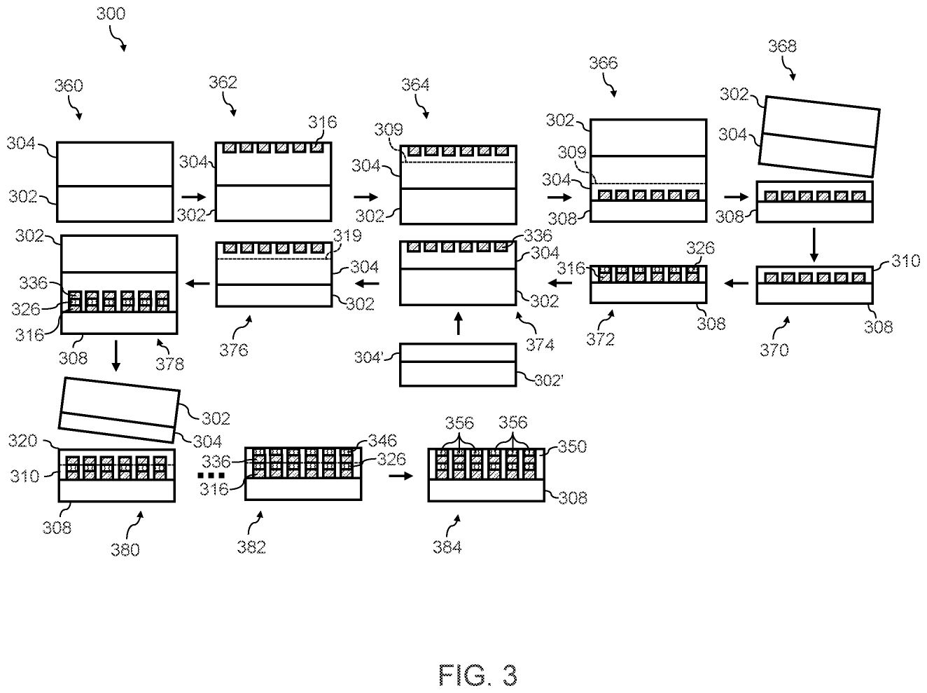

FIG. 3 depicts an overview of an example method 300 according to example embodiments of the present disclosure. FIG. 3 is intended to represent structures for identification and description and is not intended to represent the structures to physical scale. The method 300 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 360, the method 300 may include forming a wide bandgap epitaxial layer 304 on a growth substrate 302. The growth substrate 302 may be a semiconductor material. For instance, the growth substrate 302 may be a silicon substrate, a silicon carbide substrate, a sapphire substrate, or other suitable substrate. In some embodiments, the substrate 302 may be a semi-insulating silicon carbide substrate that may be, for example, the 4H polytype of silicon carbide. Other suitable substrates may be used as the growth substrate 302 without deviating from the scope of the present disclosure.

The wide bandgap epitaxial layer 304 may be formed by epitaxial growth on the growth substrate 302. The wide bandgap epitaxial layer 304 may be, in some embodiments, a silicon carbide epitaxial layer. The wide bandgap epitaxial layer 304 may be, in some embodiments, a Group III-nitride. The wide bandgap epitaxial layer 304 may be formed using any suitable epitaxial growth process, such as hybrid vapor phase epitaxy (HVPE), metal-organic vapor phase epitaxy (MOVPE), molecular beam epitaxy (MBE), or other suitable growth process.

At 362, the method 300 may include implanting dopants into the wide bandgap epitaxial layer 304 to form one or more first doped regions 316. For instance, a high energy implant process may create the one or more first doped regions 316 in the wide bandgap epitaxial layer 304. The dopants may be implanted using a dopant implantation process (e.g., ion implantation process). Alternatively, the first doped regions 316 may be formed during the epitaxial growth process of the wide bandgap epitaxial layer 304.

In some embodiments, the dopants implanted into the wide bandgap epitaxial layer may be selected such that the first doped regions 316 have a first conductivity type (e.g., such that the first doped regions are n-type). In some embodiments, the dopants implanted into the wide bandgap epitaxial layer may be selected such that the first doped regions 316 have a second conductivity type (e.g. such that the second doped regions are p-type). The implant conditions associated with the implant process may be selected to provide a desired or specified dopant concentration in the first doped regions 316. For instance, the dose and energy of implanted dopants may be selected during the implant process to provide a desired dopant concentration for the first doped regions 316.

At 364, the method 300 may include providing a separation plane 309 in the wide bandgap epitaxial layer 304. In some embodiments, forming the separation plane may include implanting one or more species (e.g., hydrogen) into the wide bandgap epitaxial layer 304. The species may induce damage in the wide bandgap epitaxial layer to form the separation plane 309. In some embodiments, forming the separation plane may include emitting one or more lasers into the wide bandgap epitaxial layer 304 to form a laser damaged region in the wide bandgap epitaxial layer along the separation plane 309. In some embodiments, the separation plane 309 does not extend through the first doped regions 316.

At 366, the method 300 may include bonding the first surface of the wide bandgap epitaxial layer 304 onto the substrate 308. In some embodiments, the substrate 308 may be a carrier substrate. In some embodiments, the substrate 308 may include silicon carbide or polycrystalline silicon carbide. Other suitable substrates may be used as the substrate 308 without deviating from the scope of the present disclosure, such as a silicon substrate or a sapphire substrate.

The wide bandgap epitaxial layer 304 may be bonded to the substrate 308 using a bonding process. The bonding process may be a direct bonding or fusion bonding process where the wide bandgap epitaxial layer 304 is directly bonded to the carrier substrate 308 with no intervening structures or layers between the substrate 108 and the wide bandgap epitaxial layer 304. The direct bonding process may be based, for instance, on van der Waals forces, covalent bonds, or other bonding between the substrate 308 and the wide bandgap epitaxial layer 304. A plasma pretreatment process or other pretreatment process may be performed on the surface(s) of the substrate 308 and/or the wide bandgap epitaxial layer 304 to prepare for the direct bonding of the wide bandgap epitaxial layer 304 to the substrate 308.

At 368, the method may include separating a portion of the wide bandgap epitaxial layer 304 to provide a first semiconductor layer 310 remaining on the substrate 308. An assembly including the substrate 308 and first semiconductor layer 310 is illustrated at 370. In some embodiments, the wide bandgap epitaxial layer 304 may be separated along the separation plane 309.

At 372, the method 300 may include implanting dopants into a second surface of the first semiconductor layer 310 to form one or more second doped regions 326 in the first semiconductor layer 310. This may occur prior to providing a second semiconductor layer on the first semiconductor layer 310 as described below.

For instance, the second doped regions 326 may be implanted such that the first semiconductor layer 310 includes the first doped regions 316 proximate a first surface of the first semiconductor layer 310 and second doped regions 326 proximate a second surface of the first semiconductor layer 310. In some instances, the second surface may be opposite the first surface of the first semiconductor layer 310. In some embodiments, the one or more second doped regions 326 may be identical in conductivity type and/or dopant concentration to the one or more first doped regions 306. In some embodiments, the one or more second doped regions 326 may include different conductivity type and/or dopant concentration relative to the one or more first doped regions 316. For instance, the first doped regions 316 and second doped regions 326 may each have a first conductivity type. For example, the first doped regions 316 and second doped regions 326 may be p-type regions. In some embodiments, the first doped regions 316 may be a first conductivity type and the second doped regions 326 may be a second conductivity type. For instance, the first doped regions 316 may be p-type regions and the second doped regions 326 may be n-type regions. In some instances, the first doped regions 316 and second doped region 326 may each include a dopant concentration. The dopant concentration of the first doped regions 316 may be the same as or different from the dopant concentration of the second doped regions 326.

At 374, the method 300 may include implanting dopants into a remaining portion of the wide bandgap epitaxial layer 304 to form one or more third doped regions 336. In some embodiments, the one or more third doped regions 336 may be identical in conductivity type and/or dopant concentration to the one or more first doped regions 316 or second doped regions 326. In some embodiments, the one or more third doped regions 336 may include different conductivity type and/or dopant concentration from the one or more first doped regions 316 or second doped regions 326.

In some examples, prior to implanting dopants at 374, the method may include grinding or otherwise removing at least a part of the remaining portion of the wide bandgap epitaxial layer 304 to ensure that no remaining doped regions remain on the wide bandgap epitaxial layer 304. In this way, the implant conditions do not have to be altered to provide the one or more third doped regions 336 that are identical in conductivity type and/or concentration to the one or more first doped regions 316 or the second doped regions 326. In some examples, the location of the separation plane 309 may be selected such that the separation plane 309 does not intersect the first doped regions 316 to provide for the remaining portion of the wide bandgap epitaxial layer 304 to be free from doped regions prior to implanting dopants at 374.

In some examples, it may be desirable to leave a portion of the first doped regions 316 remaining on the wide bandgap epitaxial layer 304 prior to implanting dopants at 374. In these examples, the separation plane 309 may intersect the first doped regions 316 to provide for first doped regions 316 to be remaining on the wide bandgap epitaxial layer 304 prior to implanting dopants at 374.

In some examples, instead of using the remaining portion of the wide bandgap epitaxial layer 304 on the growth substrate 302, the method 300 may use a new epitaxial layer 304′ on a different growth substrate 302′. At 374, the method 300 may include implanting dopants into the new wide bandgap epitaxial layer 304 to form one or more second doped regions 326. In some embodiments, the one or more second doped regions 326 may be identical in conductivity type and/or concentration to the one or more first doped regions 316. In some embodiments, the one or more second doped regions 326 may have different conductivity type and/or concentration relative to the one or more first doped regions 316.

At 376, the method 300 may include providing a separation plane 319 in the remaining portion of the wide bandgap epitaxial layer 304. Like the separation plane 309, the separation plane 319 may include implanting one or more species into the wide bandgap epitaxial layer 304 or emitting one or more lasers into the wide bandgap epitaxial layer 304. The separation plane 319 does not extend through the one or more third doped regions 336.

At 378, the method 300 may include bonding the remaining portion of the wide bandgap epitaxial layer 304 on a second surface of the first semiconductor layer 310. The remaining portion of the wide bandgap epitaxial layer 304 may be positioned and bonded to the first semiconductor layer 310 to align and stack the third doped regions 336 with the first doped regions 316 and second doped regions 326. In some embodiments, the first, second, and third doped regions may be staggered from each other or otherwise unaligned.

The wide bandgap epitaxial layer 304 may be bonded to the first semiconductor layer 310 using a bonding process. The bonding process may be a direct bonding or fusion bonding process where the wide bandgap epitaxial layer 304 is directly bonded to the first semiconductor layer 310 with no intervening structures or layers between the first semiconductor layer 310 and the wide bandgap epitaxial layer 304. The direct bonding process may be based, for instance, on van der Waals forces, covalent bonds, or other bonding between the first semiconductor layer 310 and the wide bandgap epitaxial layer 304. A plasma pretreatment process or other pretreatment process may be performed on the surface(s) of the first semiconductor layer 310 and/or the wide bandgap epitaxial layer 304 to prepare for the direct bonding of the wide bandgap epitaxial layer 304 to the first semiconductor layer 310.

At 380, the method 300 includes separating a second portion of the remaining portion of the wide bandgap epitaxial layer 304 on the first semiconductor layer 310. In other words, the remaining portion of the wide bandgap epitaxial layer 304 may be separated from the first semiconductor layer 310 such that a second semiconductor layer 320 is bonded to the second surface of the first semiconductor layer 310. In some embodiments, the second semiconductor layer 320 may be bonded to the first semiconductor layer 310 to form a stacked arrangement. In some embodiments, the first semiconductor layer 310 and second semiconductor layer 320 may be stacked such that the first doped regions 316, the second doped regions 326, and the third doped regions 326 are aligned and stacked. In some embodiments, the first semiconductor layer 310 and second semiconductor layer 320 may be stacked such that the first doped regions 316, the second doped regions 326, and the third doped regions 336 are unaligned.

At 382, the method 300 may include implanting dopants to form one or more fourth doped regions 346 in the first semiconductor layer 310. For instance, the fourth doped regions 346 may be implanted such that the second semiconductor layer 320 includes the third doped regions 336 proximate a first surface of the second semiconductor layer 320 and fourth doped regions 346 proximate a second surface of the second semiconductor layer 320. In some instances, the second surface may be opposite the first surface of the second semiconductor layer 320.

In some embodiments, the one or more fourth doped regions 346 may be identical in conductivity type and/or dopant concentration to the one or more third doped regions 336. In some embodiments, the one or more fourth doped regions 346 may include different conductivity type and/or dopant concentration relative to the one or more third doped regions 336.

In some embodiments, the first semiconductor layer 310 and second semiconductor layer 320 may each have a thickness in a range of about 0.05 microns to about 200 microns, such as about 1 microns to about 100 microns, such as about 10 microns to about 50 microns. In some embodiments, the first semiconductor layer 310 and the second semiconductor layer 320 may have about the same thickness. In some embodiments, the first semiconductor layer 310 and the second semiconductor layer 320 may have different thicknesses. The first semiconductor layer 310 and second semiconductor layer 320 may also include different materials. In some embodiments, the first semiconductor layer 310 and the second semiconductor layer 320 may each include silicon carbide or a Group III-nitride.

The operations and process discussed in 372-380 of FIG. 3 may be repeated to form a plurality of semiconductor layers on the substrate 308. For instance, the operations shown in 372-380 may be performed to create a first semiconductor layer 310 and a second semiconductor layer 320 with four doped regions on the substrate 308. For instance, the second semiconductor layer 320 may include the third doped region 336 proximate a first surface of the second semiconductor layer 320 and a fourth doped region 346 proximate a second surface of the second semiconductor layer 320. In some embodiments, the second surface may be opposite the first surface of the second semiconductor layer 320. The third doped regions 336 and fourth doped regions 346 may be similar in conductivity type and/or concentration to the first doped regions 316 and second doped regions 326. In some instances, all four doped regions are identical in conductivity type and/or concentrations. In some embodiments, the four doped regions alternate in conductivity type.

A semiconductor device 350 with two semiconductor layers 310 and 320 are depicted at 384 of FIG. 3. The semiconductor device 350 may include deep implant regions 356 in an semiconductor structure on the substrate 308. In some embodiments, a second growth substrate, as depicted in FIG. 6, may be used instead of the remaining portion of the wide bandgap epitaxial layer 304 to complete and repeat the operations depicted in 372-380.

FIG. 3 depicts a semiconductor device 350 with two semiconductor layers for purposes of illustration and discussion. Those of ordinary skill in the art, using the disclosures provided herein, will understand that the semiconductor device 350 may include more or fewer semiconductor layers without deviating from the scope of the present disclosure. In some embodiments, additional semiconductor layers may be provided on the backside of the substrate 308.

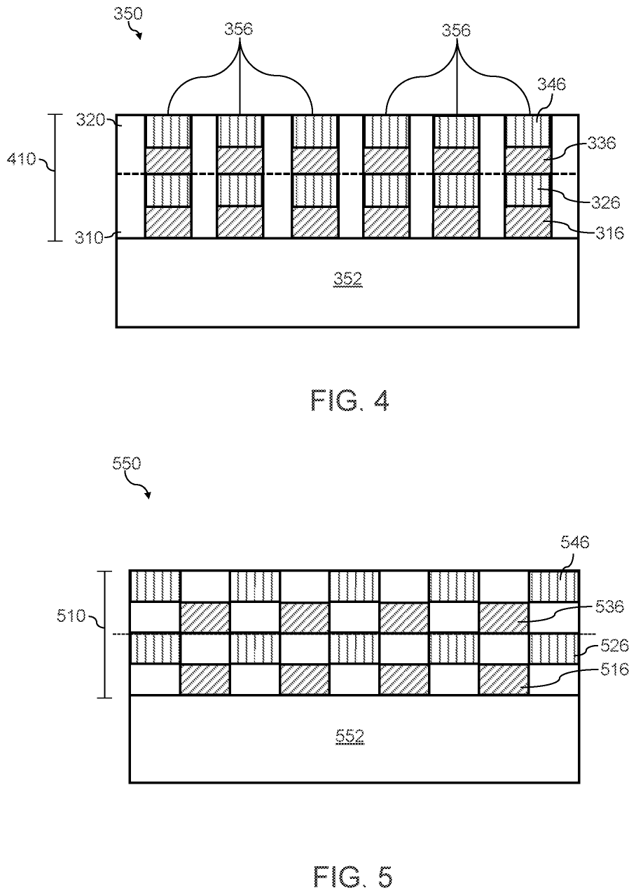

FIG. 4 depicts a cross-sectional view of an example semiconductor device 350 according to example embodiments of the present disclosure. The semiconductor device 350 may include the substrate 352 (e.g., carrier substrate 308 of FIG. 3) and a plurality of semiconductor layers 410. In some embodiments, the plurality of semiconductor layers 410 may be bonded to one another in a stacked arrangement. The plurality of semiconductor layers 410 may include several layers, for instance a first semiconductor layer 310 and a second semiconductor layer 320 as depicted in FIG. 3. The plurality of semiconductor layers 410 may each include a plurality of doped regions which align and stack to create a plurality of deep implant regions 356 (e.g., doped columns). In some embodiments, each doped region may be different (e.g., different doping concentration, different doping species, different doping profile, etc.), creating distinct doped regions for each of the plurality of semiconductor layers 410.

As shown, the semiconductor device 350 may include a second semiconductor layer 320 with one or more third doped regions 336. The plurality of semiconductor layers 410 may be stacked and arranged such that the third doped regions 336 align and stack with the first doped regions 316 and second doped regions 326. The third doped regions 336 may be similar to the first doped regions 316 and second doped regions 326. For instance, the third doped regions 336, as well as the first and second doped regions, may have a conductivity type and a dopant concentration. The conductivity type and dopant concentration of the third doped regions 336 may be the same as the first doped regions 316 and second doped regions 326 or may be different.

In some embodiments, the second semiconductor layer 320 may include one or more fourth doped regions 346. The plurality of semiconductor layers 410 may be stacked and arranged such that the fourth doped regions 446 align and stack with the first doped regions 316, second doped regions 326, and third doped regions 336. The fourth doped regions 346 may be similar to the first doped regions 316, second doped regions 326, and third doped regions 336. For instance, the fourth doped regions 346, as well as the first doped region 316, second doped region 326, and third doped region 336, may have a conductivity type and a dopant concentration. The conductivity type and dopant concentration of the fourth doped regions 346 may be the same as the other doped regions or may be different.

Each of the plurality of semiconductor layers 410 may have a thickness. The thickness of each layer may be in a range of about 0.05 microns to about 200 microns, such as about 1 micron to about 100 microns, such as about 10 microns to about 50 microns. In some embodiments, each of the plurality of semiconductor layers 410 may have the same thickness relative to one another. In some embodiments, one or more of the plurality of semiconductor layers 410 may have a different thickness.

Each of the plurality of semiconductor layers 410 may be a wide bandgap semiconductor, such as silicon carbide or a Group III-nitride. The stacked layer structure of the semiconductor device 350 may be used to form a variety of semiconductor devices, such as silicon carbide-based non-charge-balanced devices and charge-balanced (superjunction) devices (e.g., SBDs, JFETs, IGBTs MOSFETs) or complex devices, such as Bipolar-CMOS-DMOS (BCD) devices.

FIG. 5 depicts a cross-sectional view of a semiconductor device 550 according to examples embodiments of the present disclosure. The semiconductor device 550 may be a variation to the semiconductor device(s) 150, 350, depicted in FIGS. 2 and 4. The semiconductor device 550 includes a plurality of semiconductor layers 510 on a substrate 552 according to example embodiments discussed herein. In some embodiments, the plurality of semiconductor layers 510 may include the one or more first doped regions 516, one or more second doped regions 526, one or more third doped regions 536, and one or more fourth doped regions 546.

As depicted, the one or more first doped regions 516, one or more second doped regions 526, one or more third doped regions 536, and one or more fourth doped regions 546 may be staggered such that the one or more doped regions are not vertically aligned (e.g., are unaligned). The configuration depicted in FIG. 5 is for example purposes only. It should be appreciated that any configuration of the one or more doped regions may be created using the methods disclosed herein. In some embodiments, the sets of one or more doped regions may have the same or different conductivity types and/or dopant concentrations.

FIG. 6 depicts an overview of an example method 600 according to example embodiments of the present disclosure. The method 600 depicts a parallel process for stacking semiconductor layers on a substrate (e.g., carrier substrate) according to example embodiments of the present disclosure. FIG. 6 is intended to represent structures for identification and description and is not intended to represent the structures to physical scale. The method 600 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 660, the method 600 may include forming a first wide bandgap epitaxial layer 604 on a first growth substrate 602 and a second wide bandgap epitaxial layer 614 on a second growth substrate 612. The first and second growth substrates 602, 612 may be a semiconductor material. For instance, the growth substrates 602, 612 may each be a silicon substrate, a silicon carbide substrate, a sapphire substrate, or other suitable substrate. In some embodiments, the growth substrates 602, 612 may be a semi-insulating silicon carbide substrate that may be, for example, the 4H polytype of silicon carbide. Other suitable substrates may be used as the growth substrates 602, 612 without deviating from the scope of the present disclosure. The growth substrates 602, 612 may be of the same material or different materials.

A first wide bandgap epitaxial layer 604 is formed on the first growth substrate 602. A second wide bandgap epitaxial layer 614 is formed on the second growth substrate 612. The epitaxial layers 604, 614 may be formed by epitaxial growth. The epitaxial layers 604, 614 may be, in some embodiments, a silicon carbide epitaxial layer. The epitaxial layers 604, 614 may be, in some embodiments, a Group III-nitride. The epitaxial layers 604, 614 may be formed using any suitable epitaxial growth process, such as hybrid vapor phase epitaxy (HVPE), metal-organic vapor phase epitaxy (MOVPE), molecular beam epitaxy (MBE), or other suitable growth process.

At 662, the method 600 may include implanting dopants into the wide bandgap epitaxial layers 604, 614 to form one or more first doped regions 606 and one or more second doped regions 616. For instance, a high energy implant process may create the one or more first doped regions 606 in the first wide bandgap epitaxial layer 604 and the one or more second doped regions 616 in the second wide bandgap epitaxial layer 614.

At 664, the method 600 may include providing a first separation plane 609 in the first wide bandgap epitaxial layer 604 and a second separation plane 619 in the second wide bandgap epitaxial layer 614. In some embodiments, forming the separation planes 609, 619 may include implanting one or more species into the wide bandgap epitaxial layers 604, 614 or emitting one or more lasers into the wide bandgap epitaxial layers 604, 614.

At 666, the method 600 may include bonding the first surface of the first wide bandgap epitaxial layer 604 onto the first substrate 608 and bonding the first surface of the second wide bandgap epitaxial layer 614 onto the second substrate 618. In some embodiments, the substrates 608, 618 may be carrier substrates. For example, the substrates 608, 618 may be or include silicon carbide or polycrystalline silicon carbide.

At 668, the method may include separating a portion of the first wide bandgap epitaxial layer 604 to provide a first semiconductor layer 610 remaining on the first substrate 608 and separating a portion of the second wide bandgap epitaxial layer 614 to provide a second semiconductor layer 620 remaining on the second substrate 618. In some embodiments, the wide bandgap epitaxial layers 604, 614 may be separated along their respective separation planes 609, 619.

At 670, the method 600 may include flipping the second substrate 618 and second semiconductor layer 620 and bonding a surface of the second semiconductor layer 620 to a surface of the first semiconductor layer 610. In addition, at 670, the method 600 may include providing a third separation plane 629 in the remaining portion of the second substrate 618. Similar to the first separation plane 609 and the second separation plane 619, forming the third separation plane 629 may include implanting one or more species into the second substrate 618 or emitting one or more lasers into the second substrate 618.

At 672, the method 600 includes separating the remaining portion of the second substrate 618 from the second semiconductor layer 620. In other words, the remaining portion of the second substrate 618 may be separated from the second semiconductor layer 620 such that the second semiconductor layer 620 is left bonded to the surface of the first semiconductor layer 610. In some embodiments, the second semiconductor layer 620 may be bonded to the first semiconductor layer 610 to form a stacked arrangement. The first semiconductor layer 610 and second semiconductor layer 620 may be stacked such that the first doped regions 606 are aligned and stacked with the second doped regions 616. In some embodiments, the first doped regions 606 may be staggered with the second doped regions 616.

In some examples, the third separation plane 629 does not intersect the doped regions in the second semiconductor layer 620. As shown at 672, this may lead to a remaining portion of the second substrate 618 on the second semiconductor layer 620. This remaining portion may be ground away or otherwise removed (e.g., using an etch process, oxidation process or other removal process) to form the structure at 674. In some examples, the third separation plane 629 does intersect the doped regions in the second semiconductor layer 620. In these examples, the remaining portion of the second substrate 618 would not have to be removed.

The operations and processes discussed in 660-668 may be repeated to form a plurality of semiconductor layers on the substrate 608. The operations and processes discussed in 660-668 may be performed in parallel, leading to significant reductions in manufacturing cycle time. For instance, the operations shown in 660-668 may be performed to create a first semiconductor layer 610, a second semiconductor layer 620, a third semiconductor layer, and a fourth semiconductor layer, and so forth on the substrate 608. In some embodiments, the sets of one or more doped regions on the substrate 608 may be aligned and stacked to form deep implant regions.

FIG. 7 depicts an overview of a parallel fabrication process 680 of semiconductor layers according to example embodiments of the present disclosure. Line 1 at 682 may be operable to fabricate a first semiconductor layer 688 removed from a portion of a wide bandgap epitaxial layer according to example aspects of the present disclosure. Line 2 at 684 may be operable to fabricate a second semiconductor layer 690 removed from a portion of a wide bandgap epitaxial layer according to example aspects of the present disclosure. Line 3 at 686 may be operable to fabricate a third semiconductor layer 692 removed from a portion of a wide bandgap epitaxial layer according to example aspects of the present disclosure. Line 1 682, Line 2 684, and Line 3 686 may be implemented in parallel. The first, second, and third semiconductor layers 688, 690, and 692 may be subsequently bonded and stacked in a downstream process to form the semiconductor structure 694.

FIG. 7 depicts three lines of parallel processing for purposes of illustration and discussion. Those of ordinary skill in the art, using the disclosures provided herein, will understand that the parallel fabrication process 680 may include more or fewer lines of producing semiconductor layers without deviating from the scope of the present disclosure.

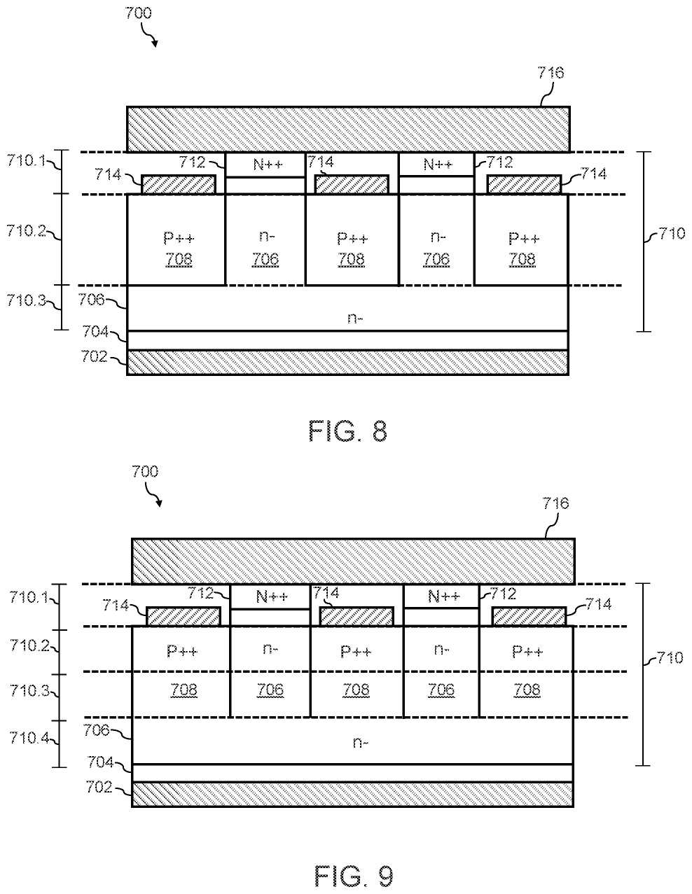

FIGS. 8 and 9 depicts a cross-sectional view of an example semiconductor device 700 according to embodiments of the present disclosure. The semiconductor device 700 may be formed using the methods disclosed herein. In some embodiments, the semiconductor device 700 may be a JFET semiconductor device. The semiconductor device 700 may include a substrate 704 with a plurality of semiconductor layers 710.1, 710.2, 710.3, . . . 710.n on the substrate 704. In some embodiments, the substrate may include silicon carbide or polycrystalline silicon carbide. The semiconductor device 700 may include a drain contact 702 on the substrate 704. The drain contact may be an ohmic contact with the substrate 704.

The example semiconductor device 700 of FIG. 8 includes three stacked layers 710.1, 710.2, 710.3. The dashed lines indicate the separation of the semiconductor layers 710.1, 710.2, 710.3. The semiconductor device 700 may include more or fewer semiconductor layers without deviating from the scope of the present disclosure. For instance, FIG. 9 illustrates that the semiconductor device 700 may have four stacked layers 710.1, 710.2, 710.3, 710.4. The dashed lines indicate the separation of the semiconductor layers 710.1, 710.2, 710.3, 710.4.

In some embodiments, the plurality of semiconductor layers 710.1, 710.2, 710.3, . . . 710.n may be bonded to one another in a stacked arrangement to form a semiconductor structure 710. The plurality of semiconductor layers 710.1, 710.2, 710.3, . . . 710.n may each be a separated portion of one or more wide bandgap epitaxial semiconductor structures and bonded in a stacked arrangement. In some embodiments, the semiconductor structure 710 may include a drift region 706. For example, at least one of the plurality of semiconductor layers 710.1, 710.2, 710.3, . . . 710.n may include an n-doped region that forms at least a portion of a drift region 706 in the semiconductor device 700. In some instances, the drift region 706 may include a first conductivity type. For example, the drift region 706 may be an n-type conductivity region. The drift region 706 may be contained within a single semiconductor layer of the plurality of semiconductor layers 710.1, 710.2, 710.3, . . . 710.n or may extend across two or more of the plurality of semiconductor layers 710.1, 710.2, 710.3, . . . 710.n.

In some embodiments, the semiconductor structure 710 may include doped columns 708 extending on and/or into the drift region 706. The doped columns 708 may extend into the drift region 706 such that a portion of the drift region 706 is between adjacent doped columns 708. In some embodiments, the doped columns 708 may extend deep into the semiconductor structure 710. For example, the doped columns may have a depth in a range of about 1 micron or greater, such as in a range of about 1 micron to about 200 microns, such as about 3 microns to about 100 microns, such as about 2 microns to about 10 microns, such as about 2 microns to about 4 microns. As depicted in FIG. 8, the doped columns 708 may be contained within a single layer of the plurality of semiconductor layers 710.1, 710.2, 710.3, . . . 710.n. In some embodiments, as depicted in FIG. 9, the doped columns 708 may extend across two or more of the plurality of semiconductor layers 710.1, 710.2, 710.3, 710.4, . . . 710.n. In some embodiments, the doped columns 708 may include a second conductivity type. For instance, the doped columns 708 may include a p-type conductivity type.

In some embodiments, the plurality of semiconductor layers 710 may include one or more source regions 712. The source regions 712 may have the first conductivity type and may by n++ regions. The semiconductor device 700 may have a source contact/source metallization 716 on the source regions 712. The source contact 716 may form an ohmic contact with the source regions 712. In some embodiments, the semiconductor structure 710 may also include one or more gate contacts 714 on the doped columns 708.

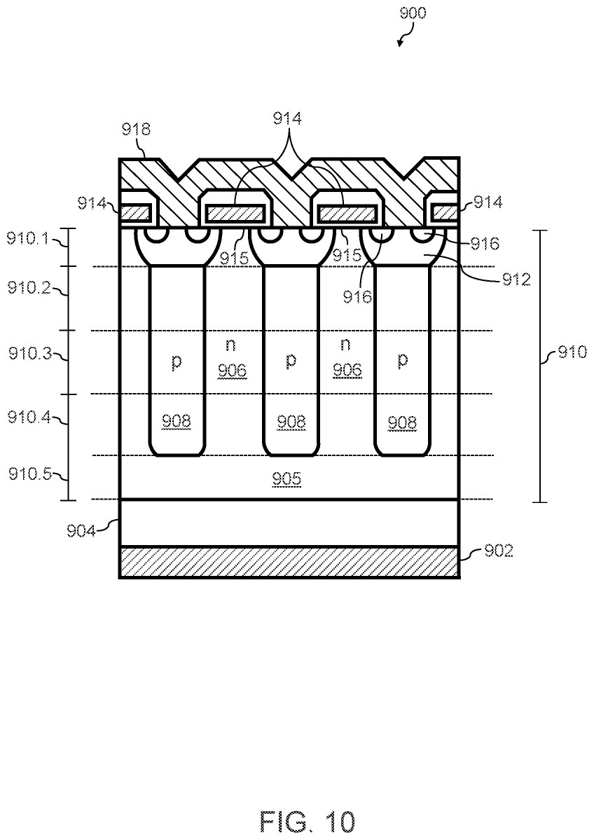

FIG. 10 depicts a cross-sectional view of an example semiconductor device 900 according to example embodiments of the present disclosure. In some embodiments, the semiconductor device 900 may be a superjunction MOSFET device. The example semiconductor device 900 includes a substrate 904 with a wide bandgap semiconductor structure 910 on the substrate 904. In some embodiments, the substrate may be silicon carbide substrate. The semiconductor device 900 may include a drain contact 902 on a surface of the substrate 904.

In some embodiments, the wide bandgap semiconductor structure 910 may include a plurality of semiconductor layers 910.1, 910.2, 910.3, 910.4, 910.5, . . . 910.n on the substrate 904. The dashed lines indicate the indicate the separation of the semiconductor layers 910.1, 910.2, 910.3, 910.4, 910.5. The semiconductor device 900 may include more or fewer semiconductor layers without deviating from the scope of the present disclosure.

The plurality of semiconductor layers 910.1, 910.2, 910.3, 910.4, 910.5, . . . 910.n may be bonded to each other and may form a stacked arrangement. In some embodiments, each of the plurality of semiconductor layers 910.1, 910.2, 910.3, 910.4, 910.5, . . . 910.n may be a separated portion of one or more wide bandgap epitaxial semiconductor structures. For instance, the plurality of semiconductor layers 910.1, 910.2, 910.3, 910.4, 910.5, . . . 910.n may be formed and bonded together in accordance with any of the methods provided herein. In some embodiments, the plurality of semiconductor layers 910.1, 910.2, 910.3, 910.4, 910.5, . . . 910.n may each include silicon carbide.

In some embodiments, the semiconductor structure may include a drift region 906., The drift region 906 may have a first conductivity type. For example, the drift region 906 may be n-type. In some embodiments, the plurality of semiconductor layers 910.1, 910.2, 910.3, 910.4, 910.5, . . . 910.n may include doped regions. The doped regions may be aligned and stacked to form one or more doped charge-compensation columns 908. The doped charge-compensation columns 908 may extend into the drift region 906 such that at least a portion of the drift region 906 is between the doped charge-compensation columns 908. In some embodiments, the doped charge-compensation columns 908 may have a second conductivity type. For example, the doped charge-compensation columns 908 may be p-type.

In some embodiments, the wide bandgap semiconductor structure 910 may include one or more well regions 912 on the doped columns 908. In some embodiments, the semiconductor structure 910 may include source regions 916 on the well regions 912. In some embodiments, each of the well region 912 and source region 916 may have an associated conductivity type. For example, the well region 912 may be p-type and the source region 916 may be n-type.

In some embodiments, the semiconductor device 900 may include a gate contact(s) (e.g. MOSFET gate electrode 914) and a source contact 918. The source contact 918 may be on the semiconductor structure 910 and more be an ohmic contact with the semiconductor structure 910. A gate insulating layer 915 (e.g., gate oxide layer) may be between the MOSFET gate electrode 914 and the semiconductor structure 910. FIG. 10 depicts an example planar gate electrode 914 for a planar MOSFET. Aspects of the present disclosure are similarly applicable to a trench gate electrode disposed in a trench in the semiconductor structure for trench gate MOSFETs.

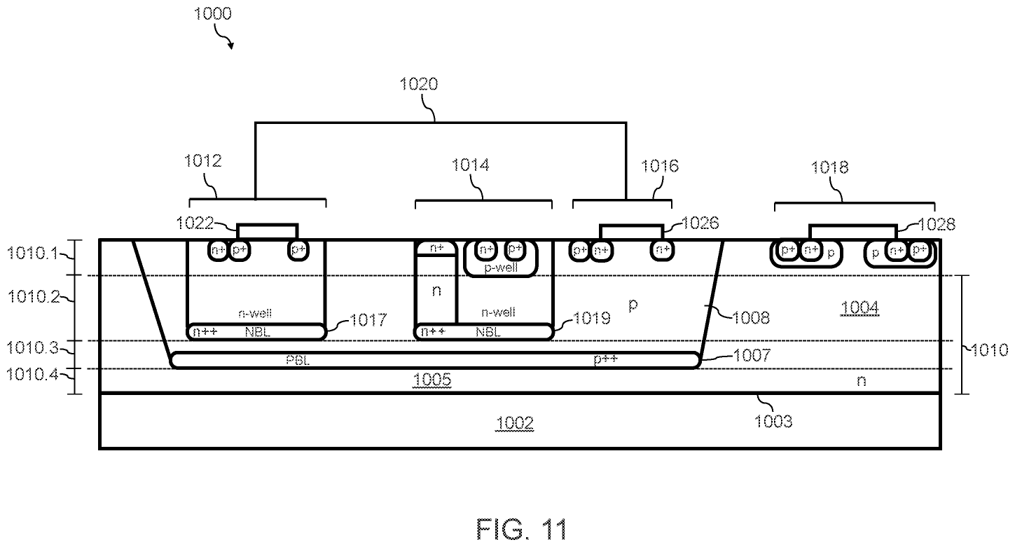

Aspects of the present disclosure allow for the fabrication of complex semiconductor devices using bonded semiconductor layers in a stacked arrangement. For instance, FIG. 11 depicts a cross-sectional view of an example semiconductor device 1000 according to examples embodiments of the present disclosure. In some instances, the semiconductor device may be a bipolar CMOS-DMOS device (BCDMOS device). The semiconductor device 1000 may include a substrate 1002 and a wide bandgap semiconductor structure 1010 on the substrate 1002. In some examples, the substrate 1002 may include silicon carbide. In some examples, the substrate 1002 may be an n++ doped substrate.

The semiconductor structure 1010 may include a plurality of semiconductor layers 1010.1, 1010.2, 1010.3, 1010.4 . . . 1010.n bonded to one another in a stacked arrangement. In some embodiments, the wide bandgap semiconductor structure 1010 may be formed according to the methods disclosed herein. In some embodiments, each of a plurality of semiconductor layers 1010.1, 1010.2, 1010.3, 1010.4 . . . 1010.n may be a separated portion of one or more wide bandgap epitaxial semiconductor structures. In some embodiments, each of the plurality of semiconductor layers 1010.1, 1010.2, 1010.3, 1010.4 . . . 1010.n may include silicon carbide.

The dashed lines indicate the indicate the separation of the semiconductor layers 1010.1, 1010.1, 1010.2, 1010.3, . . . 1010.n. The semiconductor device 1000 may include more or fewer semiconductor layers without deviating from the scope of the present disclosure. The line 1003 separating the substrate 1002 from the semiconductor layer structures denotes a bonding line where the semiconductor layers 1010.1, 1010.1, 1010.2, 1010.3, . . . 1010.n are bonded to the substrate 1002.

In some embodiments, the semiconductor structure 1010 may include a drift region 1004. The drift region 1004 may be a first conductivity type. For example, the drift region 1004 may be n-type.

The semiconductor structure 1010 may include a deep well region 1008. In some embodiments, the deep well region 1008 extends across a plurality of semiconductor layers (e.g., semiconductor layers 1010.1 and 1010.2). However, in some embodiments, the deep well region 1008 may be in a single semiconductor layer. The deep well region 1008 may have a second conductivity type. For example, the deep well region may be p-type.

The semiconductor structure may include a buffer region 1005 between the deep well region 1008 and the substrate 1002. The buffer region 1005 may be a first conductivity type, such as n-type. The buffer region 1005 may have a lower dopant concentration relative to the drift region 1004.

The deep well region may include a highly doped buried p-region (PBL region) 1007. The PBL region may be p++. The buffer region 1005 may separate the PBL region 1007 from the substrate 1002. A thickness of the buffer region 1005 may be based on a thickness of the semiconductor layer 1010.4. A distance between the PBL region 1007 and the substrate 1002 may be controlled based at least in part on a thickness of the semiconductor layer 10104.

In some embodiments, the deep well region 1008 may include a bipolar device region 1014 and a CMOS device region 1020. The bipolar device region 1014 may include doped regions to form a bipolar junction transistor device in the deep well region 1008.

In some embodiments, the deep well region 1008 may include a CMOS device region 1020. The CMOS device region 1020 may include a PMOS region 1012 and an NMOS region 1016 in the deep well region 1008. The PMOS region 1012 may include doped regions to form a PMOS device. The NMOS region 1016 may include doped regions to form an NMOS device. The PMOS region 1012 may include a highly doped buried n-region (NBL region) 1017. The NBL region 1017 may be n++. Similarly, the bipolar device region 1014 may include a highly-doped buried n-region (NBL region) 1019. The NBL region 1019 may be n++.

The semiconductor device 1000 may include a VDMOS region 1018. The VDMOS region 1018 includes doped regions sufficient to form a vertical MOSFET device. The VDMOS region 1018 may be located outside the deep well region 1008. The deep well region 1008 may be operable to electrically isolate the bipolar device region 1014 and CMOS device region 1020 from the substrate 1002.

The BCDMOS device 1000 may include one or more gate electrodes and other contacts (not illustrated). For instance, the BCDMOS device 1000 may include a gate electrode 1022 associated with the PMOS region 1012. The BCDMOS device 1000 may include a gate electrode 1026 associated with the NMOS region 1016. The BCDMOS device 1000 may include a gate electrode 1028 associated with the VDMOS region 1018.

The gate electrodes 1022, 1026, and/or 1028 may include polysilicon, in some embodiments. A gate oxide or other gate dielectric may be between the gate electrodes 1022, 1026 and/or 1028 and the semiconductor structure.

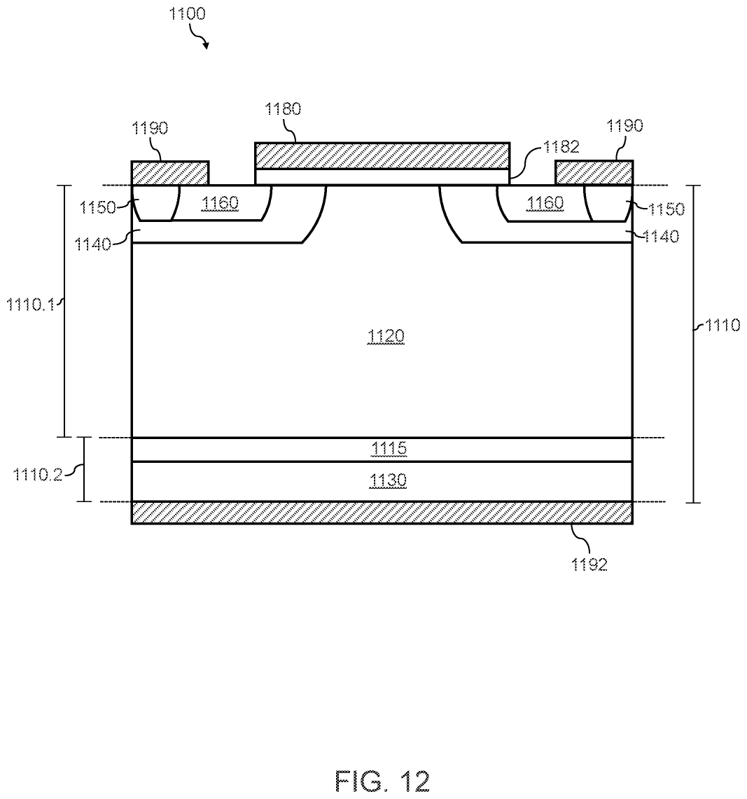

FIG. 12 depicts an example semiconductor device 1100 according to example embodiments of the present disclosure. The semiconductor device 1100 may be an IGBT. The example semiconductor device 1100 includes a semiconductor structure 1110, such as a wide bandgap semiconductor structure (e.g., silicon carbide).

In some embodiments, the semiconductor structure 1110 may include a plurality of semiconductor layers 1110.1, 1110.2, . . . 1110.n. The dashed lines indicate the indicate the separation of the semiconductor layers 1110.1 and 1110.2. The semiconductor device 1100 may include more or fewer semiconductor layers without deviating from the scope of the present disclosure.

The plurality of semiconductor layers 1110.1,1110.2 . . . , 1110.n may be bonded to each other and may form a stacked arrangement. In some embodiments, each of the plurality of semiconductor layers 1110.1,1110.2 . . . , 1110.n may be a separated portion of one or more wide bandgap epitaxial semiconductor structures. For instance, the plurality of semiconductor layers 1110.1,1110.2 . . . , 1110.n may be formed and bonded together in accordance with any of the methods provided herein. In some embodiments, the plurality of semiconductor layers 1110.1, 1110.2 . . . , 1110.n may each include silicon carbide. In some examples, the semiconductor layers 1110.1,1110.2 . . . , 1110.n may be different semiconductor materials. For instance, the semiconductor layer 1110.1 may be silicon carbide and the semiconductor layer 1110.2 may be silicon.

In some embodiments, the semiconductor layer 1110.1 may be formed on a substrate (not illustrated). The substrate may be removed (e.g., grinding, etching, oxidation, etc.). The semiconductor layer 1110.2 may be bonded to the backside of the semiconductor layer 1110.1 to form the semiconductor structure 1110.

The semiconductor device 1100 a drift region 1120 of a first conductivity type (e.g., n-type), first regions 1160 of the first conductivity type, and second regions 1140 and third regions 1150 of a second conductivity type (e.g., p-type), and respective contacts 1190, 1192 on the semiconductor structure 1110 (e.g., on opposing surfaces). A gate electrode 1180 may be on the semiconductor structure 1110. A gate insulating layer 1182 (e.g., gate oxide layer) may be between the gate electrode 1180 and the semiconductor structure 1110.

The semiconductor layer 1110.2 (e.g., the backside layer) includes a field stop region 1115 of the first conductivity type (e.g., n-type). The semiconductor layer 1110.2 includes a collector region 1130 of the second conductivity type (e.g., p-type). The semiconductor layer 1110.2 may be formed according to example aspects of the present disclosure by implanting dopants on a first side to form the collector region 1130. Dopants may then be implanted on the opposing second side to form the field stop region 1115. In some examples, the semiconductor layer 1110.2 may be silicon to provide a more efficient collector region 1130.

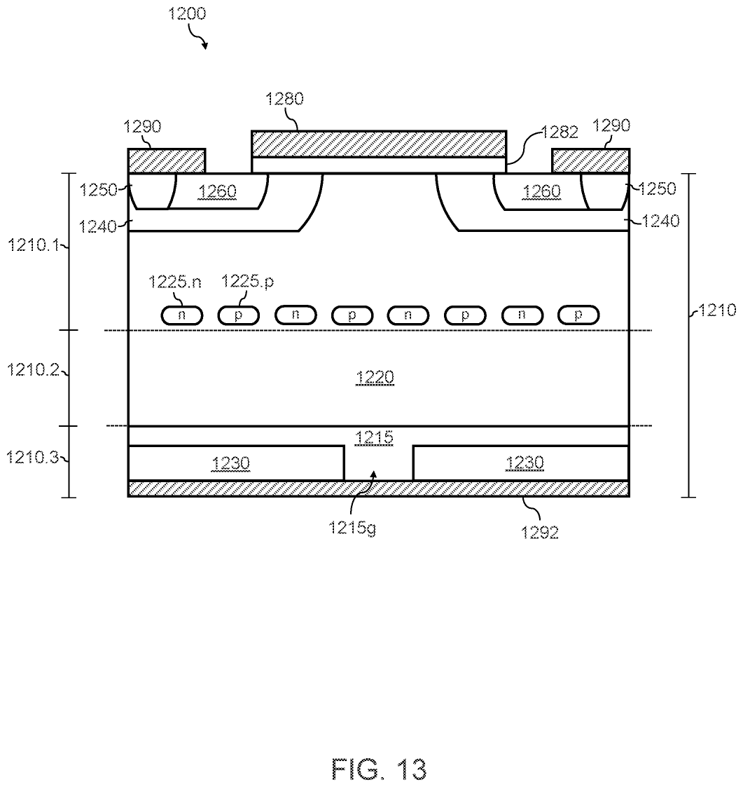

FIG. 13 depicts an example semiconductor device 1200 according to example embodiments of the present disclosure. The semiconductor device 1200 may be an IGBT. The example semiconductor device 1200 includes a semiconductor structure 1210, such as a wide bandgap semiconductor structure 1210 (e.g., silicon carbide).

In some embodiments, the semiconductor structure 1210 may include a plurality of semiconductor layers 1210.1, 1210.2, 1210.3 . . . 1210.n. The dashed lines indicate the indicate the separation of the semiconductor layers 1210.1, 1210.2, and 1210.3. The semiconductor device 1200 may include more or fewer semiconductor layers without deviating from the scope of the present disclosure.

The plurality of semiconductor layers 1210.1, 1210.2, 1210.3 . . . 1210.n may be bonded to each other and may form a stacked arrangement. In some embodiments, each of the plurality of semiconductor layers 1210.1, 1210.2, 1210.3 . . . 1210.n may be a separated portion of one or more wide bandgap epitaxial semiconductor structures. For instance, the plurality of semiconductor layers 1210.1, 1210.2, 1210.3 . . . 1210.n may be formed and bonded together in accordance with any of the methods provided herein. In some embodiments, the plurality of semiconductor layers 1210.1, 1210.2, 1210.3 . . . 1210.n may each include silicon carbide. In some examples, the semiconductor layers 1210.1, 1210.2, 1210.3 . . . 1210.n may be different semiconductor materials. For instance, the semiconductor layers 1210.1, 1210.2 may be silicon carbide and the semiconductor layer 1210.3 may be silicon.

In some embodiments, the semiconductor layers 1210.1 and 1210.2 may be formed on a substrate (not illustrated). The substrate may be removed (e.g., grinding, etching, oxidation, etc.). The semiconductor layer 1210.3 may be bonded to the backside of the semiconductor layer 1210.2 to form the semiconductor structure 1210.

The semiconductor device 1200 a drift region 1220 of a first conductivity type (e.g., n-type), first regions 1260 of the first conductivity type, and second regions 1240 and third regions 1250 of a second conductivity type (e.g., p-type), and respective contacts 1290, 1292 on the semiconductor structure 1210 (e.g., on opposing surfaces). The drift region 1220 may further include discrete minority carrier recombination sites 1225.n (e.g., n-type) and 1225.p (e.g., p-type) A gate electrode 1280 may be on the semiconductor structure 1210. A gate insulating layer 1282 (e.g., gate oxide layer) may be between the gate electrode 1280 and the semiconductor structure 1210.

The semiconductor layer 1210.3 (e.g., the backside layer that may be formed using a semiconductor layer transfer according to examples of the present disclosure) includes a field stop region 1215 of the first conductivity type (e.g., n-type). The semiconductor layer 1210.3 includes a collector region 1230 of the second conductivity type (e.g., p-type). In some examples, the semiconductor layer 1210.3 may be silicon to have a more efficient collector region 1230. The semiconductor layer 1210.3 may or may not include one or more gaps 1215.g of the first conductivity type (e.g., n-type) in the collector region 1230. The semiconductor layer 1210.3 may be formed according to example aspects of the present disclosure by implanting dopants on a first side of a semiconductor layer that will be transferred according to examples of the present disclosure to form the collector region 1230. Dopants may then be implanted on the opposing second side to form the field stop region 1215, or these dopants may alternatively be implanted into the first side before the layer transfer, that is, implanted into the same side as the collector region implant, so that both implants are completed before the semiconductor layer transfer.

FIGS. 8-13 depict example semiconductor device structures according to examples of the present disclosure. Those of ordinary skill in the art, using the disclosure provided herein, will understand that any of the methods disclosed may be used to create other semiconductor devices without deviating from the scope of the present disclosure.

Example aspects of the present disclosure are set forth below. Any of the below features or examples may be used in combination with any of the embodiments or features provided in the present disclosure.

One example aspect of the present disclosure is directed to a semiconductor device. The semiconductor device includes a substrate. The semiconductor device includes a plurality of semiconductor layers on the substrate. The plurality of semiconductor layers are bonded to one another in a stacked arrangement.

In some embodiments, the plurality of semiconductor layers comprises: a first semiconductor layer having a first doped region; a second semiconductor layer having a second doped region. The first semiconductor layer and the second semiconductor layer are in the stacked arrangement such that the first doped region is aligned with the second doped region.

In some embodiments, the first doped region and the second doped region each have a first conductivity type.

In some embodiments, the first doped region has a first conductivity type and the second doped region has a second conductivity type.

In some embodiments, the first doped region and the second doped region each comprise implanted dopants.

In some embodiments, the first doped region has a first dopant concentration and the second doped region has a second dopant concentration, the first dopant concentration being different than the second dopant concentration.

In some embodiments, the plurality of semiconductor layers comprises a third semiconductor layer having a third doped region, wherein the third semiconductor layer is in the stacked arrangement such that third doped region is aligned with the first doped region and the second doped region.

In some embodiments, the plurality of semiconductor layers comprises a first semiconductor layer having a first doped region proximate a first surface of the first semiconductor layer and a second doped region proximate a second surface of the first semiconductor layer, the second surface of the first semiconductor layer being opposite the first surface of the first semiconductor layer.

In some embodiments, the first doped region and the second doped region each comprise implanted dopants.

In some embodiments, the plurality of semiconductor layers comprises a second semiconductor layer having a third doped region proximate a first surface of the second semiconductor layer and a fourth doped region proximate a second surface of the second semiconductor layer, the second surface of the second semiconductor layer being opposite the first surface of the second semiconductor layer.

In some embodiments, the first semiconductor layer and the second semiconductor layer are in the stacked arrangement such that the first doped region, the second doped region, the third doped region, and the fourth doped region are aligned.

In some embodiments, the first doped region has a first conductivity type and the second doped region has a second conductivity type.

In some embodiments, the first doped region has a first dopant concentration and the second doped region has a second dopant concentration, the first dopant concentration being different than the second dopant concentration.

In some embodiments, the third doped region has a first conductivity type and the fourth doped region has a second conductivity type.

In some embodiments, each of the plurality of semiconductor layers has a thickness in a range of about 0.05 microns to about 200 microns.

In some embodiments, the plurality of semiconductor layers each comprise silicon carbide or a Group III-nitride.

In some embodiments, each of the plurality of semiconductor layers is a separated portion of one or more wide bandgap epitaxial semiconductor structures.

In some embodiments, a first semiconductor layer of the plurality of semiconductor layers is a different material relative to a second semiconductor layer of the plurality of semiconductor layers.

In some embodiments, the substrate comprises silicon carbide.

In some embodiments, the substrate comprises polycrystalline silicon carbide.

In some embodiments, the semiconductor device comprises a JFET, MOSFET, Schottky diode, or an IGBT.

In some embodiments, the semiconductor device comprises a bipolar-CMOS-DMOS device.

Another example aspect of the present disclosure is directed to a method for fabricating a semiconductor device. The method includes bonding first surface of a wide bandgap epitaxial layer on a first surface of a carrier substrate. The method includes separating a portion of the wide bandgap epitaxial layer to provide a first semiconductor layer remaining on the carrier substrate. The method includes bonding a second semiconductor layer on a second surface of the first semiconductor layer to form a stacked arrangement.

In some embodiments, providing a first surface of the wide bandgap epitaxial layer on a substrate comprises: forming the wide bandgap epitaxial layer on a growth substrate; implanting dopants into the wide bandgap epitaxial layer to form one or more first doped regions; providing a separation plane in the wide bandgap epitaxial layer; and providing the first surface of the wide bandgap epitaxial layer on the substrate.

In some embodiments, providing a separation plane comprises implanting one or more species into the wide bandgap epitaxial layer.

In some embodiments, providing a separation plane comprises emitting one or more lasers into the wide bandgap epitaxial layer.

In some embodiments, bonding a second semiconductor layer on the second surface of the first semiconductor layer to form a stacked arrangement comprises: implanting dopants into a remaining portion of the wide bandgap epitaxial layer after separating a portion of the wide bandgap epitaxial layer to form one or more second doped regions; providing a separation plane in the remaining portion of the wide bandgap epitaxial layer; providing the remaining portion of the wide bandgap epitaxial layer on the second surface of the first semiconductor layer; and separating a second portion of the remaining portion of the wide bandgap epitaxial layer to provide the second semiconductor layer on the first semiconductor layer.

In some embodiments, bonding a second semiconductor layer on the second surface of the first semiconductor layer to form a stacked arrangement comprises: forming a second wide bandgap epitaxial layer on a second growth substrate; implanting dopants into the second wide bandgap epitaxial layer to form one or more second doped regions; providing the second wide bandgap epitaxial layer on the second surface of the first semiconductor layer; and separating a portion of the second wide bandgap epitaxial layer to provide the second semiconductor layer on the first semiconductor layer.

In some embodiments, the method comprises implanting dopants into the second surface of the first semiconductor layer prior to providing the second semiconductor layer on the second surface of the first semiconductor layer.

In some embodiments, the first semiconductor layer has a first doped region, the second semiconductor layer has second doped region, wherein the first semiconductor layer and the second semiconductor layer are in the stacked arrangement such that the first doped region is aligned with the second doped region.

In some embodiments, the first doped region and the second doped region each have a first conductivity type.

In some embodiments, the first doped region has a first conductivity type and the second doped region has a second conductivity type.

In some embodiments, the first doped region has a first dopant concentration and the second doped region has a second dopant concentration, the second dopant concentration being different than the first dopant concentration.

In some embodiments, the first semiconductor layer has a first doped region proximate a first surface of the first semiconductor layer and a second doped region proximate a second surface of the first semiconductor layer.

In some embodiments, the first semiconductor layer and the second semiconductor layer each have a thickness in a range of about 0.05 microns to about 200 microns.

In some embodiments, the first semiconductor layer and the second semiconductor layer each comprise silicon carbide or a Group III-nitride.

In some embodiments, the carrier substrate comprises silicon carbide.

In some embodiments, the method comprises bonding a third semiconductor layer on a second surface of the carrier substrate, the second surface opposite the first surface.

Another example aspect of the present disclosure is directed to a semiconductor device. The semiconductor device includes a substrate. The semiconductor device includes a semiconductor structure comprising a plurality of semiconductor layers on the substrate. The plurality of semiconductor layers are bonded to one another in a stacked arrangement wherein at least one of the plurality of semiconductor layers comprises a doped column. The doped column having a thickness of about 2 microns or greater. The semiconductor device includes a gate contact on the doped column.

In some embodiments, the doped column is in a single semiconductor layer.

In some embodiments, the doped column extends across two or more of the plurality of semiconductor layers.

In some embodiments, the doped column comprises a P++ region.

In some embodiments, at least one of the plurality of semiconductor layers comprises an n-doped region forming a drift region of the semiconductor device.

In some embodiments, the substrate comprises a polycrystalline silicon carbide substrate.

In some embodiments, at least one of the plurality of semiconductor layers comprises one or more source regions, wherein the semiconductor device comprises a source contact on the one or more source regions.

In some embodiments, the semiconductor device further comprises a drain contact on the substrate.

In some embodiments, each of the plurality of semiconductor layers is a separated portion of one or more wide bandgap epitaxial semiconductor structures.

Another example aspect of the present disclosure is directed to a superjunction MOSFET device. The MOSFET device may include a substrate. The MOSFET device may include a semiconductor structure comprising a plurality of semiconductor layers on the substrate. The plurality of semiconductor layers are bonded to one another in a stacked arrangement. The plurality of semiconductor layers comprise a first semiconductor layer having a first doped region and a second semiconductor layer having a second doped region. The first doped region and the second doped region are aligned to form a doped column in the semiconductor structure.

In some embodiments, the superjunction MOSFET device comprises a gate contact on the semiconductor structure, a source contact on the semiconductor structure, and a drain contact on the substrate.

In some embodiments, the device includes a drift region in the semiconductor structure, wherein the doped column is on the drift region.

In some embodiments, the device includes a well region on the doped column.

In some embodiments, the device includes a source region on the well region.

In some embodiments, the plurality of semiconductor layers are bonded to one another.

In some embodiments, each of the plurality of semiconductor layers comprises silicon carbide.

In some embodiments, the substrate comprises silicon carbide.

In some embodiments, each of the plurality of semiconductor layers is a separated portion of one or more epitaxial semiconductor structures.

Another example aspect of the present disclosure is directed a bipolar CMOS-DMOS (BCDMOS) device. The BCDMOS device may include a substrate. The BCDMOS device may include a wide bandgap semiconductor structure comprising a plurality of semiconductor layers on the substrate. The plurality of semiconductor layers are bonded to one another in a stacked arrangement. The BCDMOS device may include a deep well region extending across two or more of the plurality of semiconductor layers. The deep well region comprises a bipolar device region and a CMOS device region.

In some embodiments, the device includes a VDMOS region outside the deep well region.

In some embodiments, the deep well region is operable to electrically isolate the bipolar device region and the CMOS device region from the substrate.

In some embodiments, the CMOS device region comprises an NMOS region and a PMOS region.

In some embodiments, the plurality of semiconductor layers comprises at least one semiconductor layer between the deep well region and the substrate.

In some embodiments, plurality of semiconductor layers are bonded to one another.

In some embodiments, each of the plurality of semiconductor layers comprises silicon carbide.

In some embodiments, the substrate comprises silicon carbide.

In some embodiments, each of the plurality of semiconductor layers is a separated portion of one or more wide bandgap epitaxial semiconductor structures.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a substrate; and
a plurality of semiconductor layers on the substrate, the plurality of semiconductor layers being bonded to one another in a stacked arrangement.

2. The semiconductor device of claim 1, wherein the plurality of semiconductor layers comprises:
a first semiconductor layer having a first doped region;
a second semiconductor layer having a second doped region; and
wherein the first semiconductor layer and the second semiconductor layer are in the stacked arrangement such that the first doped region is aligned with the second doped region.

3. The semiconductor device of claim 2, wherein the first doped region and the second doped region each have a first conductivity type.

4. The semiconductor device of claim 2, wherein the first doped region has a first conductivity type and the second doped region has a second conductivity type.

5. The semiconductor device of claim 2, wherein the first doped region and the second doped region each comprise implanted dopants.

6. The semiconductor device of claim 2, wherein the first doped region has a first dopant concentration and the second doped region has a second dopant concentration, the first dopant concentration being different than the second dopant concentration.

7. The semiconductor device of claim 2, wherein the plurality of semiconductor layers comprises a third semiconductor layer having a third doped region, wherein the third semiconductor layer is in the stacked arrangement such that third doped region is aligned with the first doped region and the second doped region.

8. The semiconductor device of claim 1, wherein the plurality of semiconductor layers comprises a first semiconductor layer having a first doped region proximate a first surface of the first semiconductor layer and a second doped region proximate a second surface of the first semiconductor layer, the second surface of the first semiconductor layer being opposite the first surface of the first semiconductor layer.

9. (canceled)

10. The semiconductor device of claim 8, wherein the plurality of semiconductor layers comprises a second semiconductor layer having a third doped region proximate a first surface of the second semiconductor layer and a fourth doped region proximate a second surface of the second semiconductor layer, the second surface of the second semiconductor layer being opposite the first surface of the second semiconductor layer.

11. The semiconductor device of claim 10, wherein the first semiconductor layer and the second semiconductor layer are in the stacked arrangement such that the first doped region, the second doped region, the third doped region, and the fourth doped region are aligned.

12. (canceled)

13. (canceled)

14. (canceled)

15. The semiconductor device of claim 1, wherein each of the plurality of semiconductor layers has a thickness in a range of about 0.05 microns to about 200 microns.

16. The semiconductor device of claim 1, wherein the plurality of semiconductor layers each comprise silicon carbide or a Group III-nitride.

17. The semiconductor device of claim 1, wherein each of the plurality of semiconductor layers is a separated portion of one or more wide bandgap epitaxial semiconductor structures.

18. The semiconductor device of claim 1, wherein a first semiconductor layer of the plurality of semiconductor layers is a different material relative to a second semiconductor layer of the plurality of semiconductor layers.

19. The semiconductor device of claim 1, wherein the substrate comprises silicon carbide.

20. The semiconductor device of claim 1, wherein the substrate comprises polycrystalline silicon carbide.

21. The semiconductor device of claim 1, wherein the semiconductor device comprises a JFET, MOSFET, Schottky diode, or an IGBT.

22. The semiconductor device of claim 1, wherein the semiconductor device comprises a bipolar-CMOS-DMOS device.

23. A method for fabricating a semiconductor device, comprising:
bonding first surface of a wide bandgap epitaxial layer on a first surface of a carrier substrate;
separating a portion of the wide bandgap epitaxial layer to provide a first semiconductor layer remaining on the carrier substrate; and
bonding a second semiconductor layer on a second surface of the first semiconductor layer to form a stacked arrangement.

24. The method of claim 23, wherein providing a first surface of the wide bandgap epitaxial layer on a substrate comprises:
forming the wide bandgap epitaxial layer on a growth substrate;
implanting dopants into the wide bandgap epitaxial layer to form one or more first doped regions;
providing a separation plane in the wide bandgap epitaxial layer; and
providing the first surface of the wide bandgap epitaxial layer on the substrate.

25.-38. (canceled)

39. A semiconductor device, comprising:
a substrate;
a semiconductor structure comprising a plurality of semiconductor layers on the substrate, the plurality of semiconductor layers being bonded to one another in a stacked arrangement;
wherein at least one of the plurality of semiconductor layers comprises a doped column, the doped column having a thickness of about 2 microns or greater; and
a gate contact on the doped column.

40.-65. (canceled)
